(19) United States
(12) Patent Application Publication
(10) Pub. No.: US 2024/0232455 A1
(43) Pub. Date: Jul. 11, 2024

(54) METHOD AND SYSTEM FOR AUTOMATICALLY SUGGESTING AN ENGINEERING TOOL

(71) Applicant: Siemens Industry Software Ltd., Tel Aviv (IL)

(72) Inventors: Moshe Schwimmer, Giv’at Shmuel (IL); Rafael Blumenfeld, Raanana (IL)

(21) Appl. No.: 18/559,074

(22) PCT Filed: May 28, 2021
(86) PCT No.: PCT/IB2021/054669

§ 371 Date: Nov. 6, 2023

(51) Int. Cl. G06F 30/17; G06F 16/248

(52) U.S. Cl. CPC G06F 30/17; G06F 16/248

(57) ABSTRACT

A method for automatically creating a list of computer-implemented engineering tools that are designed for solving an engineering problem includes detecting a series of interactions of a user with a main software tool which aim to solve the engineering problem by way of the main software tool. Each detected identified interaction is temporally tagged in order to create a time series of the interactions. A semantic construct is automatically created from the time series. Then there is automatically performed a semantic search in a library of computer-implemented engineering tools which includes a semantics description of each computer-implemented engineering tool, and is configured for identifying at least one computer-implemented engineering tool whose semantics description matches the semantic construct. Then a list is automatically generated with all identified computer-implemented engineering tools and the list is displayed.

### TECHNICAL FIELD

The present disclosure is directed, in general, to computer-aided design, visualization, and manufacturing (“CAD”) systems, product lifecycle management (“PLM”) systems, product data management (“PDM”) systems, and similar systems, that manage data for products and other items (collectively, “Product Data Management” systems or PDM systems). More specifically, the disclosure is directed to computer implemented engineering tools used by engineers for determining a technical solution to a technical problem.

### BACKGROUND OF THE DISCLOSURE

Computer implemented engineering tools, hereafter also simply called “software tools” are commonly used by engineers in their daily work for solving engineering problems. It exists a large panel of such engineering tools, each one being specifically designed for solving some tasks or problems. In other words, considering an engineering problem that shall be solved, there will be software tools that are more adequate than others for solving said engineering problem. Unfortunately, it often happens that said adequate software tools are not the ones used by the engineer for solving said engineering problem. Indeed, the lack of knowledge of available solutions may result in engineers continuing to use software tools they are familiar with, even their usage is very cumbersome and may lead to sub-optimal results.

In other situations, an engineer may try to find an alternative software tool optimally designed for solving the engineering problem he is working on. Adequate software tools might be found then via internet searches, or social networks, etc. Also, alternative solutions might be provided to the engineer by a software account manager. But the provided alternative solutions will depend on the software account manager ability to identify the needs of the engineer.

The need exists thus for a tool capable of automatically indicating or suggesting an optimal software tool for solving a current engineering problem.

### SUMMARY OF THE DISCLOSURE

Various disclosed embodiments include methods, systems, and computer readable mediums for automatically creating a list of computer-implemented engineering tools designed for solving a current engineering problem a user is facing. The method includes detecting and identifying a series of interactions of a user with a main software tool, wherein said interactions aim to solve an engineering problem (e.g. by interacting with a target object modeled by the main software) by means of the main software tool. The method further includes temporally tagging each detected and identified interaction in order to create a time series of said interactions and automatically creating a semantic construct from said time series. Based on the created semantic construct, the method automatically performs a semantic search in a library of computer-implemented engineering tools, wherein said library comprises a semantics description of each computer-implemented engineering tool, and wherein said semantic search is configured for identifying at least one computer-implemented engineering tool whose semantic description matches the semantic construct. Finally, the method comprises automatically creating a list comprising each identified computer-implemented engineering tool, and displaying said list.

A data processing system comprising a processor and an accessible memory is also disclosed, wherein the data processing system is configured for implementing the previously described method.

The present invention proposes also a non-transitory computer-readable medium encoded with executable instructions that, when executed, cause one or more data processing systems to perform the previously described method.

The foregoing has outlined rather broadly the features and technical advantages of the present disclosure so that those skilled in the art may better understand the detailed description that follows. Additional features and advantages of the disclosure will be described hereinafter that form the subject of the claims. Those skilled in the art will appreciate that they may readily use the conception and the specific embodiment disclosed as a basis for modifying or designing other structures for carrying out the same purposes of the present disclosure. Those skilled in the art will also realize that such equivalent constructions do not depart from the spirit and scope of the disclosure in its broadest form.

Before undertaking the DETAILED DESCRIPTION below, it may be advantageous to set forth definitions of certain words or phrases used throughout this patent document: the terms “include” and “comprise”, as well as derivatives thereof, mean inclusion without limitation; the term “or” is inclusive, meaning and/or; the phrases “associated with” and “associated therewith”, as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, whether such a device is implemented in hardware, firmware, software or some combination of at least two of the same. It should be noted that the functionality associated with any particular controller may be centralized or distributed, whether locally or remotely. Definitions for certain words and phrases are provided throughout this patent document, and those of ordinary skill in the art will understand that such definitions apply in many, if not most, instances to prior as well as future uses of such defined words and phrases. While some terms may include a wide variety of embodiments, the appended claims may expressly limit these terms to specific embodiments.

### BRIEF DESCRIPTION OF THE DRAWINGS

For a more complete understanding of the present disclosure, and the advantages thereof, reference is now made to the following descriptions taken in conjunction with the accompanying drawings, wherein like numbers designate like objects, and in which:

FIG. 1 illustrates a block diagram of a data processing system in which an embodiment can be implemented.

FIG. 2 shows a flowchart for automatically suggesting an optimal computer-implemented engineering tool to a user according to a preferred embodiment of the invention.

### DETAILED DESCRIPTION

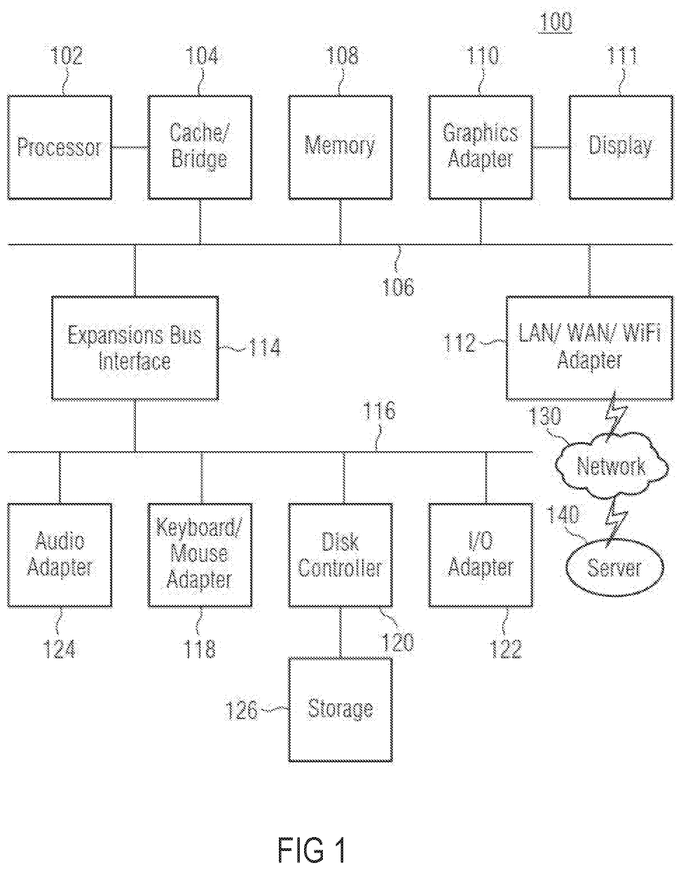

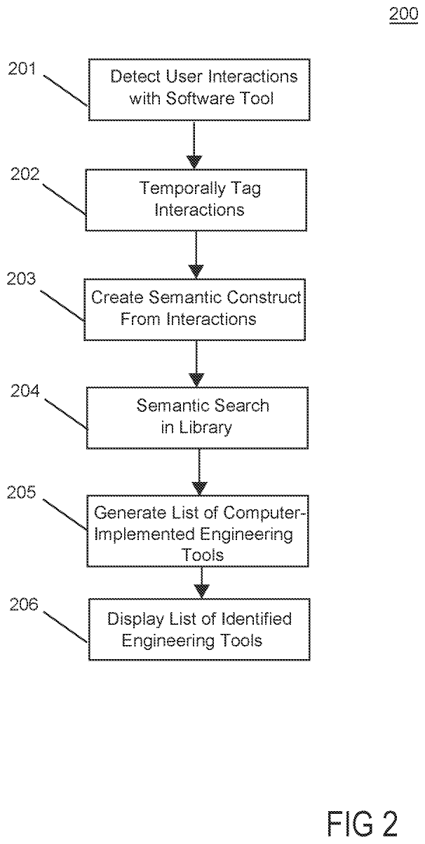

FIGS. 1 and 2, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged device. The numerous innovative teachings of the present application will be described with reference to exemplary non-limiting embodiments.

Techniques enabling to guide an engineer through already existing solution tools when said engineer is currently trying to solve an engineering problem with a main software tool that unfortunately does not offer an optimal solution are missing. The present invention enables to automatically bring to the knowledge of said engineer already existing optimal solutions. An advantage of the present invention is that the identified optimal computer-implemented engineering tools are presented in real time, i.e. when the engineer is currently searching how to solve the engineering problem. The engineer does not need to lose time in searching for alternative or optimal solutions, such solutions are directly and automatically proposed to the engineer.

FIG. 1 illustrates a block diagram of a data processing system 100 in which an embodiment can be implemented, for example as a PDM system particularly configured by software or otherwise to perform the processes as described herein, and in particular as each one of a plurality of interconnected and communicating systems as described herein. The data processing system 100 illustrated can include a processor 102 connected to a level two cache/bridge 104, which is connected in turn to a local system bus 106. Local system bus 106 may be, for example, a peripheral component interconnect (PCI) architecture bus. Also connected to local system bus in the illustrated example are a main memory 108 and a graphics adapter 110. The graphics adapter 110 may be connected to display 111.

Other peripherals, such as local area network (LAN)/Wide Area Network/Wireless (e.g. WiFi) adapter 112, may also be connected to local system bus 106. Expansion bus interface 114 connects local system bus 106 to input/output (I/O) bus 116. I/O bus 116 is connected to keyboard/mouse adapter 118, disk controller 120, and I/O adapter 122. Disk controller 120 can be connected to a storage 126, which can be any suitable machine usable or machine readable storage medium, including but are not limited to nonvolatile, hard-coded type mediums such as read only memories (ROMs) or erasable, electrically programmable read only memories (EEPROMs), magnetic tape storage, and user-recordable type mediums such as floppy disks, hard disk drives and compact disk read only memories (CD-ROMs) or digital versatile disks (DVDs), and other known optical, electrical, or magnetic storage devices.

Also connected to I/O bus 116 in the example shown is audio adapter 124, to which speakers (not shown) may be connected for playing sounds. Keyboard/mouse adapter 118 provides a connection for a pointing device (not shown), such as a mouse, trackball, trackpointer, touchscreen, etc.

Those of ordinary skill in the art will appreciate that the hardware illustrated in FIG. 1 may vary for particular implementations. For example, other peripheral devices, such as an optical disk drive and the like, also may be used in addition or in place of the hardware illustrated. The illustrated example is provided for the purpose of explanation only and is not meant to imply architectural limitations with respect to the present disclosure.

A data processing system in accordance with an embodiment of the present disclosure can include an operating system employing a graphical user interface. The operating system permits multiple display windows to be presented in the graphical user interface simultaneously, with each display window providing an interface to a different application or to a different instance of the same application. A cursor in the graphical user interface may be manipulated by a user through the pointing device. The position of the cursor may be changed and/or an event, such as clicking a mouse button, generated to actuate a desired response.

One of various commercial operating systems, such as a version of Microsoft Windows™, a product of Microsoft Corporation located in Redmond, Wash. may be employed if suitably modified. The operating system is modified or created in accordance with the present disclosure as described.

LAN/WAN/Wireless adapter 112 can be connected to a network 130 (not a part of data processing system 100), which can be any public or private data processing system network or combination of networks, as known to those of skill in the art, including the Internet. Data processing system 100 can communicate over network 130 with server system 140, which is also not part of data processing system 100, but can be implemented, for example, as a separate data processing system 100.

As used herein, the terms computer-implemented engineering tool or software tool refer to engineering software tools used during engineering activities including, but not limited to, modeling of an object, simulating object or processes, calculating, measuring, predicting, collecting, controlling, documenting, etc. They are tools designed for helping an engineer in his engineering tasks.

The present invention basically proposes to match, preferentially in interactive time (i.e. during or after a user session with the main software tool) or real time, an engineering activity defined by the interactions an engineer has with a main software tool, with a semantic description of a computer-implemented engineering tool that would optimally enable the engineer to accomplish said engineering activity. For instance, defined from interactions said engineer has with one or several HMI,

FIG. 2 is a block diagram schematically illustrating the method according to the invention and will be used for providing a more detailed description of the present invention.

At step 201, a series of interactions of a user with a main software tool is detected by the system according to the invention. Said system is typically a data processing system 100 as previously described. For instance, the data processing system might be configured for detecting an interaction of the user with one or several human machine interfaces, hereafter HMI. Said series of interactions with the HMI is configured for controlling the main software tool, i.e. it enables the user to control the main software tool for performing some engineering activities like modeling, or simulating physical behaviors, or estimating or calculating physical values. For instance, the user uses said one or several HMI for interacting with a target object modeled by means of the main software tool. Said HMI may comprise a keyboard, and/or a mouse, and/or a touchscreen, and/or any other device enabling the user to control and/or to interact with the main software tool, i.e. with hardware configured for running or implementing said main software tool. A signal outputted by an HMI and resulting from the interaction of the user with said HMI might be analyzed by the system according to the invention in order to detect said series of interactions. Commands or log files of HMI related software and/or of the main software tool might be tracked by the system according to the invention to detect and identify said interactions. The system might thus be configured for tracking a mouse and/or keyboard and/or touch screen user interaction. The system might also be configured for analyzing said log file(s) and/or a command of the main software tool, and/or mapping an activity of the main software tool.

Interactions with the main software tool by means of an HMI might comprise using a mouse for selecting an object or for opening a menu, a scrolling action, a creation of an object, a drag operation, using a keyboard shortcut, etc. In order to detect such interactions, and as already explained, the system is preferentially configured for analyzing the log files of the main software tool. It can thus not only detect the interaction, but also determine which type of action (e.g. selecting an object, drawing an object, dragging an object, opening or closing a new session, opening or closing a window, etc.) is performed by means of the main software tool. Preferentially, some specific interactions of the user with the main software tool might be used by the system according to the invention for triggering or launching said detection of said series of interactions. Said specific interactions define typically a context or scope of the interaction of the user with the main software tool. Said specific interactions comprise for instance: an opening and/or closing of a user main software tool session, an opening and/or closing of a window of the main software tool, a command related to a change of a tool (e.g. drawing tool, calculating tool, simulating tool, etc.) of the main software tool, a command related to a change of activity within the main software tool (e.g. using a calculating tool after using a drawing tool of the main software tool). Preferentially, each series of interaction detected by the system starts with a first of said specific interactions (e.g. opening a window, or selecting a tool of the main software tool) and ends with a second of said specific interactions (e.g. closing the window, or selecting another tool of the main software tool). Each series of interactions is thus related to a specific context, in connection with the user activity (e.g. drawing an object by means of the main software tool) and preferentially delimited at each “extremity” of the series of interactions by a specific interaction.

At step 202, the system is configured for temporally tagging each detected interaction in order to create, for each detected series of interactions, a time series of said interactions of the considered detected series. Preferentially, said time series of interactions is recorded in a memory or database of the system according to the invention. The temporal tagging enables the system to order the interactions of the user in function of the time. In other words, the interactions of a series of interactions can be ordered from the earliest to the latest interaction. The temporal tagging will help the system to create a semantic construct for the detected series of interactions.

At step 203, the system is configured for automatically creating a semantic construct from said time series of interactions. For this purpose and preferentially, the system is configured for automatically identifying each interaction of the time series and for automatically generating a semantic element for each identified interaction or for a predefined set of successive interactions. In other words, each identified interaction or set of successive interactions is translated by the system according to the invention into a semantic element. Preferentially, each interaction of a time series is associated to, or is, a data of a log file of the main software tool. The system uses then a semantics description of the main software tool for determining, for each interaction or for sets of successive interactions, e.g. for each or for a set of log file data of said time series, a corresponding semantic element, translating thus the time series of interactions (e.g. the time series of log file data) into a time series of semantics elements, obtaining thus a semantic construct of the time series of interactions. The description of the main software tool semantics might be stored in a memory or database of the system according to the invention, or preferentially in a library according to the invention. Said semantics description enables the system to translate the time series of interactions, e.g. a temporal sequence of identified commands or events that occurred during the running of the main software tool and that are typically recorded in said log file, into a main software tool semantics construct. Preferentially, said semantics description comprises a behavior description of the main software tool on a target object (e.g. said behavior description may comprise a set of successive log file data), a description of the target object, a property of the target object, and an identification of an engineering domain or discipline. Said semantics description enables the system to capture a scope or context of an interaction. Thanks to the semantics description of the main software tool, each time series of interactions might be associated by the system according to the invention to an engineering activity and a domain or discipline associated to the latter. Therefore, the activity and context in which the interactions take place might be determined by the system and associated to a neutral semantics construct based on the semantics description of the main software tool.

At step 204, the system automatically performs a semantic search in said library. Preferentially, a machine learning algorithm is used for performing the semantic search. Said library is a library of computer-implemented engineering tools, which comprises for each computer-implemented engineering tools, like the main software tool, a semantics description of the considered computer-implemented engineering tool. As previously described, the main software tool semantics description is preferentially included in said library. The semantics description of each computer-implemented engineering tools of said library comprises preferentially a behavior description of the considered computer-implemented engineering tool on a target object, a description of the target object, a property of the target object, and an identification of an engineering domain defined for the considered computer-engineering tool. As input for said semantic search, the system uses at least the previously obtained semantic construct. It can further automatically acquire a user input, wherein said user input is configured for specifying the current user activity, for instance by selecting or defining an engineering domain, an engineering problem, or providing activity keywords, or information about the current activity. The user input might be acquired by the system according to the invention by means of a chatbot or by enabling the user to select one or several activities among a set of displayed activities. The semantic construct might be thus configured for defining a semantics of a tool, and/or of a discipline or domain corresponding to the time series of interactions, and it corresponds to a neutral description of the activity of the user.

For said semantic search, the system is configured for automatically identifying, in said library, all computer-implemented engineering tools comprising a semantics description that matches the semantic construct. It will for instance find or identify, for instance by browsing the library by domain or discipline, computer-implemented engineering tools that comprise a semantics description focusing on the domain or discipline defined by the semantic construct. Then, among the found or identified computer-implemented engineering tools that focus on said domain or discipline, it will automatically identify the ones that comprise a similar semantic construct in their semantics description as the semantic construct created at step 203. Preferentially, the system is configured for ranking the identified computer-implemented engineering tools that comprise said similar semantic construct. The ranking can be made according to their likelihood to best match the current user activity, i.e. according to a degree of similarity with the semantic construct created at step 203, for instance from the computer-implemented engineering tool that would be the most appropriate (highest rank, i.e. highest degree of similarity with the semantic construct created at step 203) to carry out the user activity, to the least appropriate (lowest rank, i.e. lowest degree of similarity with the semantic construct created at step 203). Preferably, the ranking is based on similarity and on dissimilarity, e.g. missing constructs. For the similarity, the system according to the invention may search for similar or identical semantic elements (e.g. semantic elements belonging to same type or class), and/or similar or identical relationships (e.g. connections between nodes of a knowledge graph), and/or similar or identical properties. For this ranking, the system might also use preferentially a weighting based on a hierarchical organization or construction of the semantics description of each computer-implemented engineering tool. Each semantic construct will thus be assigned a hierarchical position or level within the semantics description of the computer-implemented engineering tool, and this hierarchical position/level will be used for assigning a weighting to the identified computer-implemented engineering tool, wherein the higher the hierarchical position or level of the semantic construct in a semantics description of a computer-implemented engineering tool, the higher the weight assigned to the computer-implemented engineering tool, and the higher the rank. This will enable the system to provide as output computer-implemented engineering tools that focus on the current task or activity perform by the user, avoiding to present as results computer-implemented engineering tools for which said task or activity is not a main feature of the considered computer-implemented engineering tool.

At step 205, the system automatically creates a list of the identified computer-implemented engineering tools and provides the latter as output. For instance, said list might be displayed on an HMI, like a screen. Preferentially, said list ranks the identified computer-implemented engineering tools according to their likelihood to best match the current user activity, i.e. according to the computer-implemented engineering tools that would be the most appropriate for solving the engineering problem faced by the user.

At step 206, the system automatically displays the created list. The user is thus automatically informed about the computer-implemented engineering tool that would be the most suitable for performing his current activity instead of using the main software tool. Optionally, the system may further automatically load and/or open, for instance in real time or in interactive time, the computer-implemented engineering tool that has the higher rank in said list. In such a case, the methods according to the invention makes it possible to automatically load and open a computer-implemented engineering tool in function of actions currently performed by a user for solving an engineering problem, automatically proposing the most appropriate tool for solving said engineering problem.

As already explained above, the system according to the invention uses a library that comprises a semantics description of all computer-implemented engineering tools and preferentially also of the main software tool. According to a preferred embodiment, each semantics description is organized in a knowledge graph. The knowledge graph of a computer-implemented engineering tool is an ontology graph that provides a structured representation of knowledge associated to the computer-implemented engineering tool by means of semantic elements, describing thus the features and relationships of the features of the computer-implemented engineering tool by means of said semantic elements. The knowledge graph is thus an ontological description of the computer-implemented engineering tool. It is preferentially obtained by creating first an ontological description of engineering disciplines and/or domains, then by extracting semantics of each computer-implemented engineering tool that has to be part of the library, wherein said extracted semantics is based on knowledge and said discipline and/or domains. The semantics description of each of said computer-implemented engineering tools is then built from said ontological description (common for all computer-implemented engineering tools of the library) and said extracted semantics (specific for each computer-implemented engineering tool). Each computer-implemented engineering tool is thus related to its own ontology, and its semantics description uses well-defined and organized semantic elements for describing the knowledge associated to the considered computer-implemented engineering tool. The semantic elements are the shared “vocabulary” used to describe the computer-implemented engineering tools.

According to the present invention, the knowledge graph is an ontological description of a computer-implemented engineering tool, for instance, of a simulation tool or calculation tool. Preferably, the knowledge graph comprises several nodes N, wherein each node is connected by an edge to at least one other node, said edge connections representing the relationships between the nodes. For instance, each node represents a semantic element. The nodes are organized into a hierarchical structure. For instance, the nodes might be organized into classes, subclasses, etc., defining different levels in the hierarchical structure. More precisely, the knowledge graph according to the invention is an instance graph, wherein the nodes represent instances of different types based on semantics definitions. For instance, an ontological description of an engineering domain may comprise a concept or construct “WEIGHT” that is a property of a body. Some computer-implemented engineering tools may comprise an “evaluate weight” tool configured for evaluating the weight of a body from volume and density properties of said body. The semantics description of the computer-implemented engineering tool might encode then an ACTION “evaluate weight” describing how the weight of a body is calculated. Consequently, since the knowledge graph is built from the domain ontology and semantics description of the computer-implemented engineering tool, it will encode said ACTION in connection with the WEIGHT. In such a case, if the semantic construct created by the system according to the invention from a time series of interactions is “ACTION, input VOLUME, input DENSITY, produce property WEIGH”, then the system according to the invention will check the knowledge graph of computer-implemented engineering tools of the library in order to determine whether the checked knowledge graph comprises a similar semantic construct. If the same semantic construct is found, for instance in a subtree of the knowledge graph, then there will be a perfect match of the semantic construct resulting in a high ranking of the computer-implemented engineering tool. If the system according to the invention finds a similar construct like “get property VOLUME, get property DENSITY, do action MULTIPLY, generate property, call it WEIGHT”, then it will correspond to a partial match of the semantic construct, resulting in a lower ranking of the concerned computer-implemented engineering tool.

Of course, those of skill in the art will recognize that, unless specifically indicated or required by the sequence of operations, certain steps in the processes described above may be omitted, performed concurrently or sequentially, or performed in a different order.

Those skilled in the art will recognize that, for simplicity and clarity, the full structure and operation of all data processing systems suitable for use with the present disclosure is not being illustrated or described herein. Instead, only so much of a data processing system as is unique to the present disclosure or necessary for an understanding of the present disclosure is illustrated and described. The remainder of the construction and operation of data processing system 100 may conform to any of the various current implementations and practices known in the art.

It is important to note that while the disclosure includes a description in the context of a fully functional system, those skilled in the art will appreciate that at least portions of the present disclosure are capable of being distributed in the form of instructions contained within a machine-usable, computer-usable, or computer-readable medium in any of a variety of forms, and that the present disclosure applies equally regardless of the particular type of instruction or signal bearing medium or storage medium utilized to actually carry out the distribution. Examples of machine usable/readable or computer usable/readable mediums include: nonvolatile, hard-coded type mediums such as read only memories (ROMs) or erasable, electrically programmable read only memories (EEPROMs), and user-recordable type mediums such as floppy disks, hard disk drives and compact disk read only memories (CD-ROMs) or digital versatile disks (DVDs).

Although an exemplary embodiment of the present disclosure has been described in detail, those skilled in the art will understand that various changes, substitutions, variations, and improvements disclosed herein may be made without departing from the spirit and scope of the disclosure in its broadest form.

None of the description in the present application should be read as implying that any particular element, step, or function is an essential element which must be included in the claim scope: the scope of patented subject matter is defined only by the allowed claims.

1-15. (canceled)

16. A method for automatically creating a list of computer-implemented engineering tools designed for solving an engineering problem, the method comprising the following steps:
a) detecting a series of interactions of a user with a main software tool, the interactions aiming to solve an engineering problem by way of the main software tool;
b) temporally tagging each detected interaction in order to create a time series of the interactions;
c) automatically creating a semantic construct from the time series of the interactions;
d) automatically performing a semantic search in a library of computer-implemented engineering tools, the library containing a semantics description of each of the computer-implemented engineering tools, and the semantic search being configured for identifying at least one computer-implemented engineering tool whose semantics description matches the semantic construct;
e) automatically generating a list with all identified computer-implemented engineering tools; and
f) displaying the list.

17. The method according to claim 16, which comprises using a machine learning algorithm for performing the semantic search.

18. The method according to claim 16, wherein the semantics description comprises, for each computer-implemented engineering tool, a behavior description of the computer-implemented engineering tool on a target object, a description of the target object, a property of the target object, and an identification of an engineering domain.

19. The method according to claim 18, wherein the semantics description is organized in a knowledge graph.

20. The method according to claim 16, which comprises identifying the series of interactions with at least one process selected from the group consisting of tracking a user interaction with a mouse, tracking a user interaction with a keyboard, tracking a user interaction with a touch screen, analyzing an HMI log file, and mapping an activity of the main software tool.

21. The method according to claim 16, wherein the step of automatically creating a semantic construct from the time series comprises:
automatically identifying each interaction of the time series; and
automatically generating a semantic element for each identified interaction or for a set of identified interactions by using a semantics description of the main software tool.

22. The method according to claim 16, comprising automatically loading and opening the at least one computer-implemented engineering tool.

23. A data processing system comprising:
a processor; and
an accessible memory connected to said processor;
the data processing system being configured to:
a) detect a series of interactions of a user with a main software tool, wherein the interactions aim to solve an engineering problem by way of the main software tool;
b) temporally tag each detected interaction in order to create a time series of the interactions;
c) automatically create a semantic construct from the time series of the interactions;
d) automatically perform a semantic search in a library of computer-implemented engineering tools, wherein the library comprises a semantics description of each computer-implemented engineering tool, and wherein the semantic search is configured for identifying at least one computer-implemented engineering tool whose semantic description matches the semantic construct;
e) automatically create a list comprising all identified computer-implemented engineering tools;
f) display said list.

24. The data processing system according to claim 23, wherein a machine learning algorithm is used for performing the semantic search.

25. The data processing system according to claim 23, wherein the semantics description comprises, for each computer-implemented engineering tool, a behavior description of the computer-implemented engineering tool on a target object, a description of the target object, a property of the target object, and an identification of an engineering domain.

26. The data processing system according to claim 25, wherein the semantics description is organized in a knowledge graph.

27. The data processing system according to claim 23, wherein, for identifying the series of interactions, the data processing system is configured to perform at least one of the processes selected from the group consisting of tracking at least one of a user interaction with a mouse, a user interaction with a keyboard, or a user interaction with a touch screen, analyzing an HMI log file, and mapping an activity of the main software tool.

28. The data processing system according to claim 23, wherein, for automatically creating a semantic construct from said time series comprises, the data processing system is configured for automatically identifying each interaction of the time series and for automatically generating a semantic element for each identified interaction or for a set of identified interactions by using a semantics description of the main software tool.

29. A non-transitory computer-readable medium encoded with executable instructions that, when executed, cause one or more data processing systems to:
a) detect a series of interactions of a user with a main software tool, the interactions aiming to solve an engineering problem by way of the main software tool;
b) temporally tag each detected interaction in order to create a time series of the interactions;
c) automatically create a semantic construct from the time series of the interactions;
d) automatically perform a semantic search in a library of computer-implemented engineering tools, wherein the library includes a semantics description of each computer-implemented engineering tool, and wherein the semantic search is configured for identifying at least one computer-implemented engineering tool whose semantic description matches the semantic construct;
e) automatically create a list comprising all identified computer-implemented engineering tools; and
f) display the list.

30. The non-transitory computer-readable medium according to claim 29, wherein a machine learning algorithm is implemented for performing the semantic search.
